(19) United States
(12) Patent Application Publication
(10) Pub. No.: US 2011/0177457 A1
(43) Pub. Date: Jul. 21, 2011

(54) MASK PATTERN GENERATING METHOD, MANUFACTURING METHOD OF SEMICONDUCTOR DEVICE, AND COMPUTER PROGRAM PRODUCT

(76) Inventors: Shimon MAEDA, Tokyo (JP); Norikazu Ooishi, Saitama (JP); Sachiko Kobayashi, Chiba (JP)

(21) Appl. No.: 12/984,190

(22) Filed: Jan. 4, 2011

(30) Foreign Application Priority Data
Jan. 15, 2010 (JP) 2010-007506

(51) Int. Cl. G03F 7/20; G06F 17/50

(52) U.S. Cl. 430/319; 716/53

(57) ABSTRACT

According to the embodiment, a pattern after lithography is derived by using a mask pattern. The mask pattern is corrected by moving a first moving target pattern so that a first evaluation value calculated with respect to this pattern after lithography satisfies a first condition. Next, a pattern after lithography is derived by using the mask pattern after correction. The mask pattern after correction is further corrected by moving a second moving target pattern so that a second evaluation value calculated with respect to this pattern after lithography satisfies a second condition.

### CROSS-REFERENCE TO RELATED APPLICATIONS

This application is based upon and claims the benefit of priority from the prior Japanese Patent Application No. 2010-7506, filed on Jan. 15, 2010; the entire contents of which are incorporated herein by reference.

### FIELD

The present embodiment typically relates to a mask pattern generating method, a manufacturing method of a semiconductor device, and a computer program product.

### BACKGROUND

In recent years, in order to highly integrate semiconductor devices, a development of a technology for miniaturizing a pattern to be formed on a wafer has been progressed. If an absolute value of an allowable dimensional error decreases with such miniaturization of a pattern, it becomes difficult to keep the pattern on the wafer within the allowable dimensional range due to the influence of the Optical Proximity Effect. Therefore, the Optical Proximity Correction (hereinafter, OPC) is performed as a pattern correction on a mask pattern in which the Optical Proximity Effect is taken into consideration.

After the mask pattern is corrected by the OPC, when a pattern (hot spot) whose possibility to be a pattern failure on the wafer is larger than a predetermined value is found, the following three methods are conventionally performed, that is, (1) correction of design layout, (2) correction of OPC script (OPC program) and reprocessing of OPC, and (3) local reprocessing of OPC.

In the case of the method (1), there is a problem in that a load to a designer is increased. In the case of the method (2), there is a problem in that a long period of time is required for completing a desired mask pattern. In the case of the method (3), there is a problem in that a process of joining a region that is locally cut off for reprocessing the OPC and a region in which the OPC is not reprocessed at a seam portion, a dissection process, and the like become complicated. Moreover, when the hot spot is not eliminated by the processes of (1) to (3), any of the processes of (1) to (3) needs to be repeatedly performed until the hot spot is eliminated. As described above, reduction of the hot spots requires time and effort, so that it is desired to reduce the hot spots accurately in a short time.

### BRIEF DESCRIPTION OF THE DRAWINGS

FIG. 1 is a diagram for explaining a concept of a pattern generation according to an embodiment;

FIG. 2 is a block diagram illustrating a configuration of a pattern generating apparatus according to the embodiment;

FIG. 3 is a flowchart illustrating a generating process procedure of a mask pattern;

FIG. 4 is a flowchart illustrating a calculating process procedure of a first example of a second evaluation value;

FIG. 5 is a diagram for explaining the first example of the second evaluation value;

FIG. 6 is a flowchart illustrating a calculating process procedure of a second example of the second evaluation value;

FIG. 7 is a diagram for explaining the second example of the second evaluation value;

FIG. 8 is a flowchart illustrating a calculating process procedure of a third example of the second evaluation value;

FIG. 9 is a diagram for explaining the third example of the second evaluation value;

FIG. 10 is a flowchart illustrating a setting process procedure of a moving amount of the mask pattern;

FIG. 11 is a diagram for explaining a mask dimensional constraint condition;

FIG. 12 is a diagram for explaining a mask allowable range with respect to the mask dimensional constraint condition shown in FIG. 11;

FIG. 13 is a diagram illustrating an example of an experimental matrix with respect to the mask allowable range shown in FIG. 12;

FIG. 14 is a diagram illustrating a correspondence relationship between the experimental matrix and a lithography simulation result;

FIG. 15 is a diagram illustrating a correspondence relationship between the experimental matrix and the lithography simulation result in a case where an item whose determination result is OK is more than one;

FIG. 16 is a flowchart illustrating a setting process procedure in a case where the moving amount of the mask pattern is set by using an MEEF table;

FIG. 17 is a diagram illustrating an example of the MEEF table;

FIG. 18 is a diagram for explaining a mask pattern example in a case where both of a Neck error and a Bridge error are present;

FIG. 19A is a diagram illustrating an example of the MEEF table in a case where a pitch is 100 nm;

FIG. 19B is a diagram illustrating an example of the MEEF table in a case where a pitch is 120 nm;

FIG. 20A to FIG. 20F are diagrams for explaining a moving target edge to be an extraction target;

FIG. 21 is a flowchart illustrating a generating process procedure of the mask pattern in a case where a hot spot is eliminated while increasing the moving target edge; and

FIG. 22 is a diagram illustrating a hardware configuration of the pattern generating apparatus.

### DETAILED DESCRIPTION

According to an embodiment, a pattern after lithography is derived by using a mask pattern. A first evaluation value is calculated with respect to this pattern after lithography. Then, the mask pattern is corrected by moving a first moving target pattern in the mask pattern so that the first evaluation value satisfies a first condition. Next, a pattern after lithography is derived by using the mask pattern after correction. A second evaluation value is calculated with respect to this pattern after lithography. Then, the mask pattern after correction is further corrected by moving a second moving target pattern in the mask pattern after correction so that the second evaluation value satisfies a second condition.

A mask pattern generating method, a manufacturing method of a semiconductor device, and a computer program product according to the embodiment will be explained below in detail with reference to the accompanying drawings. The present invention is not limited to this embodiment. In the following, explanation is given for a correction method of a mask pattern (OPC) as a graphics processing method of the mask pattern that is design data on a semiconductor integrated circuit device.

### Embodiment

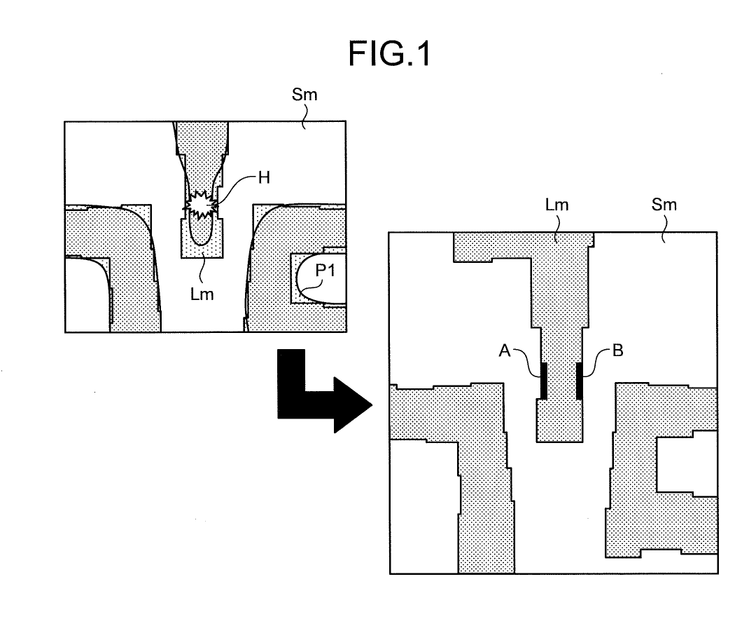

FIG. 1 is a diagram for explaining a concept of a pattern generation according to an embodiment. Design layout data corresponding to a pattern (on-wafer pattern) that needs to be formed on a substrate such as a wafer is generated in advance. Then, a lithography target is generated by using this design layout data, and pattern data (mask data) on a mask pattern is generated by using the lithography target. The lithography target is a pattern to be a target that needs to be formed on a resist by performing a lithography process (exposure process and development process). The pattern data on the mask pattern is a pattern that needs to be formed on a photomask or the like or a pattern that needs to be formed on a template or the like used in an imprint method. FIG. 1 illustrates the case in which the mask pattern is formed by a line pattern Lm and a space pattern Sm.

After the mask data is generated, a resist pattern P1 in the case of performing the exposure and development processes on a wafer by using a mask manufactured by using this mask data is derived. Then, a hot spot H in the resist pattern P1 is extracted based on the shape of the resist pattern P1 and the mask pattern (mask data) is corrected to eliminate the hot spot H. In the present embodiment, a first evaluation value and a second evaluation value are prepared as evaluation values used when evaluating presence or absence of the hot spot H.

One edge point (not shown) is set as a determination position (simulation point) of the hot spot H on the mask pattern and a difference (divergence value) between a lithography simulation result and the lithography target at the set edge point is set as the first evaluation value. When the first evaluation value is not within a predetermined allowable range, the edge point is determined as the hot spot H. The edge point becomes a target for pattern correction when the hot spot H is found.

Moreover, the second evaluation value is an evaluation value different from the first evaluation value. Specifically, opposing two side edge patterns (edge A and edge B) are set as determination targets (simulation points) of the hot spot H on the mask pattern. The edges A and B are sides (lines) arranged in parallel in a parallel direction on the line pattern, and the distance between the edge A and the edge B is a line width. Then, an inter-edge distance calculated by using the lithography simulation result with respect to the set edges A and B is set as the second evaluation value. The edges A and B are edges on the mask pattern after being changed because the hot spot H is found based on the first evaluation value. When the second evaluation value is not within a predetermined allowable range, the edges A and B are determined as the hot spot H. The edges A and B become a target for the pattern correction (position movement) when the hot spot H is found.

First, the hot spot H is extracted from the mask pattern based on whether the first evaluation value is within the allowable range, and the mask pattern is corrected to eliminate this hot spot H.

Then, the hot spot H is extracted from the mask pattern based on whether the second evaluation value is within the allowable range, and the mask pattern after correction is further corrected to eliminate this hot spot H. In the following explanation, the mask pattern before correction is defined as a pre-correction mask pattern. Moreover, the mask pattern after corrected based on the first evaluation value is defined as a first post-correction pattern, and the mask pattern after corrected based on the second evaluation value is defined as a second post-correction pattern.

In this manner, in the present embodiment, the first post-correction pattern is generated from the pre-correction mask pattern, and the second post-correction pattern is generated from the first post-correction pattern by applying the second evaluation value as an index.

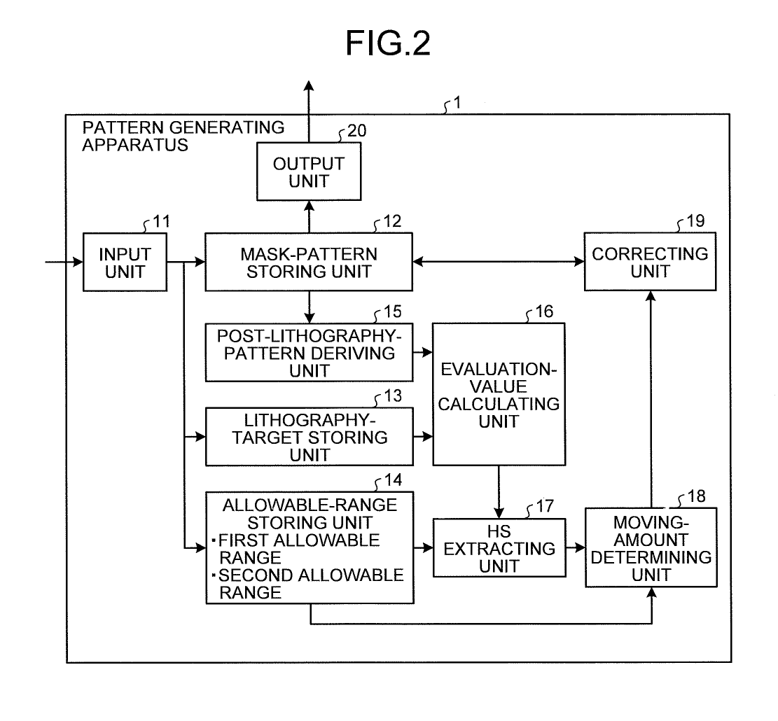

FIG. 2 is a block diagram illustrating a configuration of a pattern generating apparatus according to the embodiment. A pattern generating apparatus 1 is, for example, a computer that extracts the hot spot H by using two different evaluation indexes and corrects the mask pattern to eliminate the hot spot H. The pattern generating apparatus 1 extracts the hot spot H by using the first evaluation value and corrects the mask pattern to eliminate this hot spot H, and thereafter, extracts the hot spot H by using the second evaluation value and corrects the mask pattern to eliminate this hot spot H.

The pattern generating apparatus 1 includes an input unit 11, a mask-pattern storing unit 12, a lithography-target storing unit 13, an allowable-range storing unit 14, a post-lithography-pattern deriving unit 15, an evaluation-value calculating unit 16, an HS extracting unit 17, a moving-amount determining unit 18, a correcting unit 19, and an output unit 20.

The input unit 11 inputs the mask pattern, the lithography target, the allowable range (first allowable range) of the first evaluation value, the allowable range (second allowable range) of the second evaluation value, and the like. The input unit 11 sends the input mask pattern to the mask-pattern storing unit 12 and sends the lithography target to the lithography-target storing unit 13. Moreover, the input unit 11 sends the input first and second allowable ranges to the allowable-range storing unit 14.

The mask-pattern storing unit 12 is, for example, a memory that stores therein the mask pattern. The mask-pattern storing unit 12 stores therein the pre-correction pattern, and the first post-correction pattern and the second post-correction pattern that are corrected to eliminate the hot spot H. The lithography-target storing unit 13 is, for example, a memory that stores therein the lithography target, and the allowable-range storing unit 14 is, for example, a memory that stores therein the first allowable range and the second allowable range.

The post-lithography-pattern deriving unit 15 derives a pattern after lithography as a post-lithography pattern by using the mask pattern (pre-correction mask pattern or first post-correction pattern) in the mask-pattern storing unit 12. The post-lithography-pattern deriving unit 15 calculates the post-lithography pattern, for example, by the lithography simulation. The post-lithography-pattern deriving unit 15 sends the calculated post-lithography pattern to the evaluation-value calculating unit 16. In the following explanation, the post-lithography pattern derived by using the pre-correction mask pattern is called a first post-lithography pattern, and the post-lithography pattern derived by using the first post-correction pattern is called a second post-lithography pattern.

The evaluation-value calculating unit 16 calculates the first evaluation value based on the first post-lithography pattern derived by the post-lithography-pattern deriving unit 15 and the lithography target in the lithography-target storing unit 13. The evaluation-value calculating unit 16 sets one edge point (simulation point) as a position (determination position of the hot spot H) at which the first evaluation value is calculated and calculates the first evaluation value at this edge point.

Moreover, the evaluation-value calculating unit 16 calculates the second evaluation value based on the second post-lithography pattern derived by the post-lithography-pattern deriving unit 15 and the lithography target in the lithography-target storing unit 13. The evaluation-value calculating unit 16 sets the edges A and B (simulation points) and the like as positions (determination positions of the hot spot H) at which the second evaluation value is calculated and calculates the second evaluation value at the edges A and B. The evaluation-value calculating unit 16 sends the calculated first evaluation value to the HS extracting unit 17. Moreover, the evaluation-value calculating unit 16 sends the calculated second evaluation value to the HS extracting unit 17.

The HS extracting unit 17 extracts the hot spot H based on the first evaluation value calculated by the evaluation-value calculating unit 16 and the first allowable range in the allowable-range storing unit 14. Moreover, the HS extracting unit 17 extracts the hot spot H based on the second evaluation value calculated by the evaluation-value calculating unit 16 and the second allowable range in the allowable-range storing unit 14.

When the first evaluation value is not within the first allowable range, the HS extracting unit 17 extracts the edge point corresponding to this first evaluation value. Moreover, when the second evaluation value is not within the second allowable range, the HS extracting unit 17 extracts the edge corresponding to this second evaluation value. The HS extracting unit 17 sends the extracted hot spot H to the moving-amount determining unit 18.

The moving-amount determining unit 18 determines a moving amount at the mask pattern position corresponding to the hot spot H with respect to the hot spot H extracted by the HS extracting unit 17. When the HS extracting unit 17 extracts the hot spot H based on the first allowable range, the moving-amount determining unit 18 determines the moving amount of the edge point that is the determination position of the hot spot H based on the first allowable range. The moving-amount determining unit 18 correlates the determined moving amount with the pre-correction mask pattern to be a moving target and sends it to the correcting unit 19.

Moreover, when the HS extracting unit 17 extracts the hot spot H based on the second allowable range, the moving-amount determining unit 18 determines the moving amount of the edges A and B and the like that are the determination positions of the hot spot H based on the second allowable range. The moving-amount determining unit 18 correlates the determined moving amount with the first post-correction pattern to be the moving target and sends it to the correcting unit 19.

The correcting unit 19 corrects the mask pattern in the mask-pattern storing unit 12 based on the moving amount determined by the moving-amount determining unit 18. When the moving amount of the simulation point is determined based on the first allowable range, the correcting unit 19 generates the first post-correction pattern by correcting the pre-correction mask pattern. The correcting unit 19 stores the generated first post-correction pattern in the mask-pattern storing unit 12.

Moreover, when the moving amount of the simulation point is determined based on the second allowable range, the correcting unit 19 generates the second post-correction pattern by correcting the first post-correction pattern. The correcting unit 19 stores the generated second post-correction pattern in the mask-pattern storing unit 12. The output unit 20 outputs the second post-correction pattern stored in the mask-pattern storing unit 12 to an external device or the like.

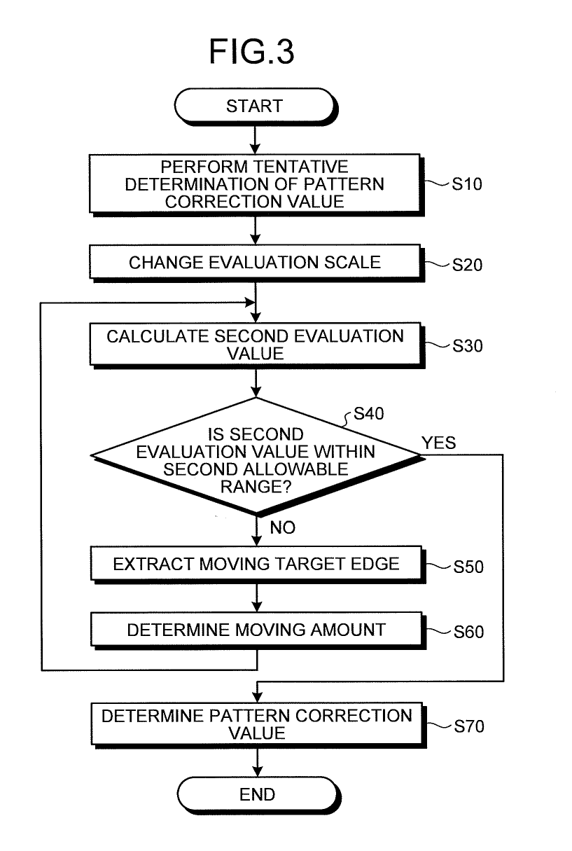

Next, a generating process procedure (correcting process procedure) of the mask pattern is explained. FIG. 3 is a flowchart illustrating the generating process procedure of the mask pattern. In the pattern generating apparatus 1, the pre-correction mask pattern and the lithography target are input from the input unit 11 in advance, and are stored in the mask-pattern storing unit 12 and the lithography-target storing unit 13 respectively. Moreover, the first allowable range and the second allowable range are input from the input unit 11 and are stored in the allowable-range storing unit 14.

The pattern generating apparatus 1 performs a tentative determination (OPC) of a pattern correction value that is the moving amount of the mask pattern (Step S10). The pattern generating apparatus 1 performs the tentative determination of the pattern correction value, for example, by a conventional method. Specifically, the post-lithography-pattern deriving unit 15 calculates the first post-lithography pattern by applying the lithography simulation to the pre-correction mask pattern in the mask-pattern storing unit 12. Then, the evaluation-value calculating unit 16 calculates the first evaluation value based on the first post-lithography pattern derived by the post-lithography-pattern deriving unit 15 and the lithography target in the lithography-target storing unit 13. At this time, the evaluation-value calculating unit 16 sets the simulation point as a position at which the first evaluation value is calculated, and calculates the first evaluation value at this simulation point. The HS extracting unit 17 extracts the hot spot H based on the first evaluation value calculated by the evaluation-value calculating unit 16 and the first allowable range in the allowable-range storing unit 14.

The moving-amount determining unit 18 determines the moving amount of the mask pattern corresponding to the hot spot H extracted by the HS extracting unit 17. At this time, the moving-amount determining unit 18 determines the moving amount of the mask pattern near the simulation point to eliminate the hot spot H based on the first allowable range in the allowable-range storing unit 14. The correcting unit 19 corrects the pre-correction mask pattern by moving the mask pattern by the determined moving amount and thereby generates the first post-correction pattern. The correcting unit 19 stores the generated first post-correction pattern in the mask-pattern storing unit 12.

Thereafter, the pattern generating apparatus 1 changes the evaluation scale (Step S20), and corrects the first post-correction pattern. Specifically, the pattern generating apparatus 1 changes the evaluation scale from the first evaluation value to the second evaluation value and corrects the first post-correction pattern. First, the post-lithography-pattern deriving unit 15 calculates the second post-lithography pattern by applying the lithography simulation to the first post-correction pattern in the mask-pattern storing unit 12. Then, the evaluation-value calculating unit 16 calculates the second evaluation value based on the second post-lithography pattern derived by the post-lithography-pattern deriving unit 15 and the lithography target in the lithography-target storing unit 13 (Step S30). At this time, the evaluation-value calculating unit 16, for example, sets the edges A and B as positions at which the second evaluation value is calculated and calculates the second evaluation value at the edges A and B.

The HS extracting unit 17 determines whether the edges A and B are the hot spot H based on whether the second evaluation value calculated by the evaluation-value calculating unit 16 is within the second allowable range in the allowable-range storing unit 14 (Step S40). For example, in the case of determining a Neck error (open error) that is an error in which a width of a line pattern becomes thin, a width of a lithography simulation image (distance between the edges A and B) is determined. Moreover, in the case of determining a Bridge error (short error) in which line patterns stick with each other, an inter-space distance (for example, distance between an edge adjacent to the edge B and the edge B) of the lithography simulation image is determined.

When the second evaluation value is not within the second allowable range (No at Step S40), the positions of the edges A and B (mask pattern corresponding to the edges A and B) become the hot spot H. Therefore, when the second evaluation value is not within the second allowable range, the HS extracting unit 17 extracts the edges A and B as moving target edges that are moved on the mask pattern (Step S50).

Then, the moving-amount determining unit 18 determines the moving amount of the mask pattern corresponding to the hot spot H extracted by the HS extracting unit 17 (Step S60). At this time, the moving-amount determining unit 18 determines the moving amount of the edges A and B to eliminate the hot spot H based on the second allowable range in the allowable-range storing unit 14.

Thereafter, the evaluation-value calculating unit 16 calculates the second evaluation value in the case where the edges A and B are moved by the moving amount determined by the moving-amount determining unit 18 (Step S30). Then, the HS extracting unit 17 determines whether the edges A and B are the hot spot H based on whether the second evaluation value calculated by the evaluation-value calculating unit 16 is within the second allowable range in the allowable-range storing unit 14 (Step S40).

When the second evaluation value is not within the second allowable range (No at Step S40), the HS extracting unit 17 extracts the hot spot H and the moving target edge (Step S50). Then, the moving-amount determining unit 18 determines the moving amount of the mask pattern corresponding to the moving target edge extracted by the HS extracting unit 17 (Step S60). In the pattern generating apparatus 1, the processes at Steps S30 to S60 are repeated until the second evaluation value falls within the second allowable range. In other words, the pattern generating apparatus 1 determines the moving amount of the edges A and B so that the second evaluation value falls within the second allowable range.

When the second evaluation value falls within the second allowable range (Yes at Step S40), the correcting unit 19 determines the moving amount of the edges A and B as the pattern correction value (Step S70). Then, the correcting unit 19 generates the second post-correction pattern by correcting the first post-correction pattern (edges A and B) by the determined pattern correction value. The correcting unit 19 stores the generated second post-correction pattern in the mask-pattern storing unit 12.

When a plurality of the hot spots H is present on the pre-correction mask pattern, the pattern generating apparatus 1 performs the process at Step S10 on the mask pattern corresponding to each hot spot H. At this time, the pattern generating apparatus 1, for example, performs the process at Step S10 on all of patterns of the mask pattern. Moreover, when a plurality of the hot spots H is present on the first post-correction pattern, the pattern generating apparatus 1 performs the processes at Steps S20 to S70 on the mask pattern corresponding to each hot spot H. At this time, the pattern generating apparatus 1 can perform the processes at Steps S20 to S70 only on a predetermined pattern (for example, the hot spot H extracted based on the pre-correction mask pattern) of the mask pattern or can perform the processes at Steps S20 to S70 on all of patterns of the mask pattern.

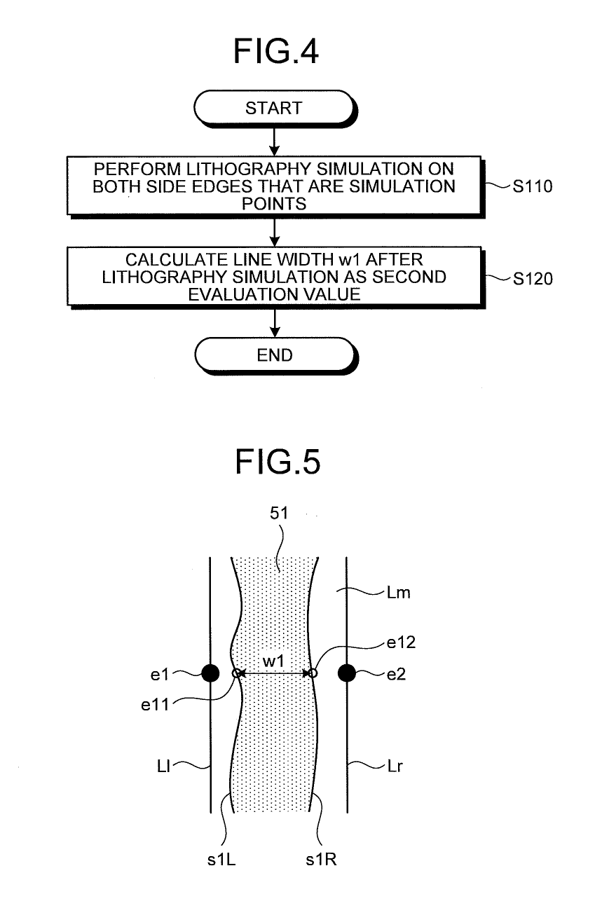

Specific examples (first example to third example) of the second evaluation value are explained. The simulation point for the second evaluation value is set by changing or adding the evaluation point that is the simulation point set when calculating the first evaluation value with respect to this evaluation point. FIG. 4 is a flowchart illustrating a calculating process procedure of the first example of the second evaluation value. The evaluation-value calculating unit 16 sets a plurality of simulation points on the mask pattern as the determination target positions of the hot spot H. The simulation point in this example is two edge points opposing on the line pattern Lm of the mask pattern, and the inter-edge-point distance of the two edge points after the lithography simulation is the second evaluation value. The second evaluation value can be a space dimension after the lithography simulation.

FIG. 5 is a diagram for explaining the first example of the second evaluation value. FIG. 5 illustrates the case where the inter-edge-point distance of the two edge points after the lithography simulation is the second evaluation value. The evaluation-value calculating unit 16 sets two edge points e1 and e2 as the simulation points with respect to the line pattern Lm on the mask pattern.

For example, when the edge point e1 is the simulation point in the case of calculating the first evaluation value, the evaluation-value calculating unit 16 sets the edge points e1 and e2 as the simulation points in the case of calculating the second evaluation value.

Specifically, the evaluation-value calculating unit 16 sets the edge point e1 on a left-side edge line L1 of the line pattern Lm on the mask pattern and sets the edge point e2 on a right-side edge line Lr. Therefore, the distance between the edge point e1 and the edge point e2 becomes the line pattern width on the mask pattern.

The evaluation-value calculating unit 16 performs the lithography simulation on both side edges (edge points e1 and e2) on the line pattern Lm that are the simulation points (Step S110). Specifically, a second post-lithography pattern 51 that is the post-lithography pattern of the line pattern Lm is derived by performing the lithography simulation on the line pattern Lm that is the mask pattern. In the second post-lithography pattern 51, the edge line corresponding to the edge line L1 is s1L and the edge line corresponding to the edge line Lr is s1R. The positions of the edge points e1 and e2 after the lithography are post-lithography edge points ell and e12, which are positioned on the edge lines s1L and s1R, respectively. The evaluation-value calculating unit 16 calculates the inter-edge-point distance (line width w1) between the post-lithography edge point ell and the post-lithography edge point e12 as the second evaluation value (Step S120).

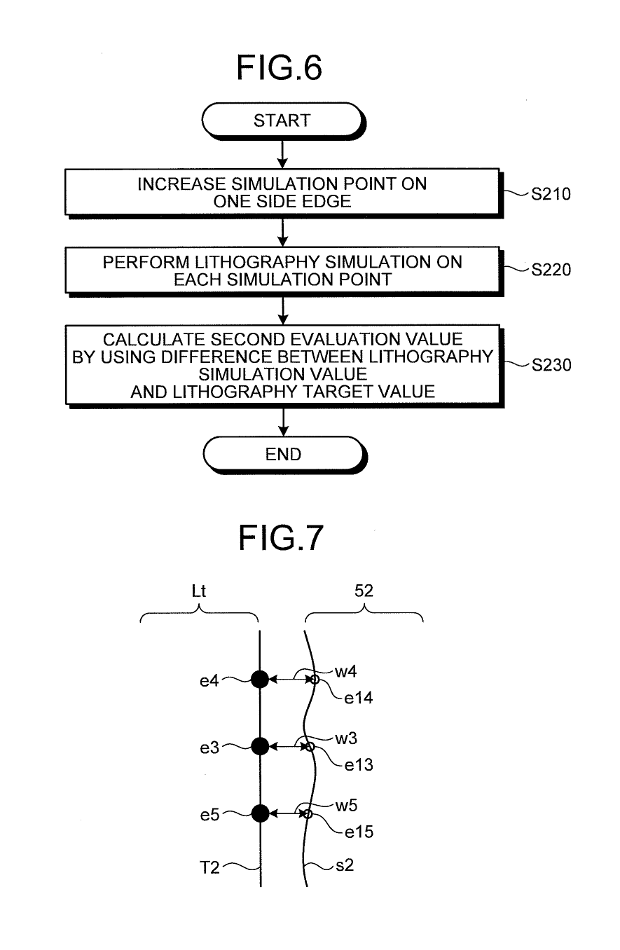

FIG. 6 is a flowchart illustrating the calculating process procedure of the second example of the second evaluation value. The evaluation-value calculating unit 16 sets a plurality of simulation points on one side line of the mask pattern as the determination target positions of the hot spot H. Specifically, the evaluation-value calculating unit 16 sets a plurality of edge points as the simulation points on one side edge line on the line pattern Lm. In other words, whereas one simulation point is set to one segment (moving target) in the first evaluation value, the simulation point is increased in one segment in the second evaluation value to set a plurality of simulation points (Step S210). In this example, a displacement amount (average value) between the positions of a plurality of edge points after the lithography simulation and the lithography target is the second evaluation value.

FIG. 7 is a diagram for explaining the second example of the second evaluation value. FIG. 7 illustrates the case where the difference between the lithography simulation result in the case where a plurality of edge points is set on one side edge and the lithography target is the second evaluation value. FIG. 7 illustrates the simulation points on the lithography target, and the lithography simulation values are calculated by using the simulation points (not shown) on the mask pattern.

The evaluation-value calculating unit 16 sets a plurality of edge points e103 to e105 (not shown) on one side edge as the simulation points with respect to the line pattern Lm on the mask pattern. For example, the evaluation-value calculating unit 16 sets the edge points e103 to e105 on the right-side edge line of the line pattern on the mask pattern, thereby setting edge points e3 to e5 on a right-side edge line T2 of a line pattern Lt on the lithography target. Therefore, the line connecting the edge points e3 to e5 becomes the edge line T2 on the lithography target of the line pattern Lt. The simulation points are arranged, for example, every 10 nm or 5 nm.

The evaluation-value calculating unit 16 performs the lithography simulation on the edge points e103 to e105 on the line pattern Lm as the simulation points (Step S220). Specifically, the lithography simulation is performed on the mask pattern thereby deriving a second post-lithography pattern 52 that is a pattern of the line pattern Lm after the lithography. In the second post-lithography pattern 52, the edge line corresponding to the edge line T2 is s2. The positions of the edge points e103 to e105 after the lithography are post-lithography edge points e13 to e15, respectively, which are positioned on the edge line s2. The evaluation-value calculating unit 16 calculates the average of respective distances between the positions (lithography simulation values) of the post-lithography edge points e13 to e15 and the edge points e3 to e5 of the lithography target as the second evaluation value. In other words, the evaluation-value calculating unit 16 calculates the average of the differences between the lithography simulation values and the lithography target values as the second evaluation value (Step S230).

Specifically, the evaluation-value calculating unit 16 calculates each of a distance w3 between the post-lithography edge point e13 and the edge point e3 of the lithography target, a distance w4 between the post-lithography edge point e14 and the edge point e4 of the lithography target, and a distance w5 between the post-lithography edge point e15 and the edge point e5 of the lithography target. Then, the evaluation-value calculating unit 16 calculates the average of the distances w3 to w5 as the second evaluation value.

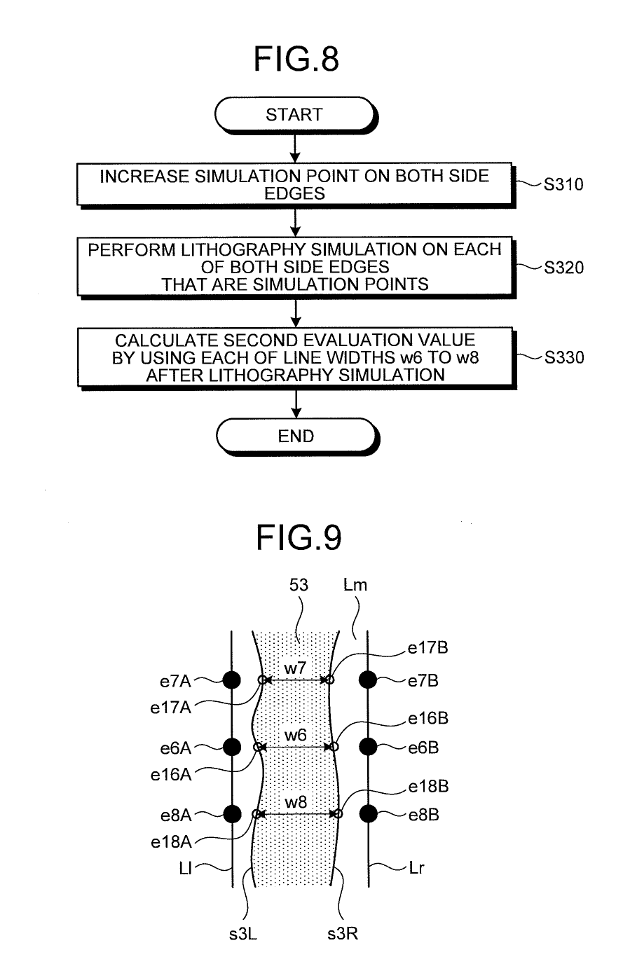

FIG. 8 is a flowchart illustrating the calculating process procedure of a third example of the second evaluation value. In the third example, an evaluation index obtained by combining the first example and the second example is set as the second evaluation value. The evaluation-value calculating unit 16 sets a plurality of simulation points (edge points) on each of both side edges on the line pattern Lm on the mask pattern as the determination target positions of the hot spot H. Specifically, the evaluation-value calculating unit 16 sets the simulation points by setting a plurality of pairs of edge points, each pair including two edge points opposing on the line pattern Lm of the mask pattern. In other words, the evaluation-value calculating unit 16 increases an edge point that is the simulation point with respect to the first evaluation value and sets an edge point opposing this edge point as the simulation point (Step S310). In this example, the distance (average) of a plurality of pairs of edge points after the lithography is the second evaluation value.

FIG. 9 is a diagram for explaining the third example of the second evaluation value. FIG. 9 illustrates the case where the inter-edge-point distance of a plurality of pairs of edge points on both side edges after the lithography simulation is the second evaluation value. The evaluation-value calculating unit 16 sets a plurality of pairs of edge points on both side edges as the simulation points of the line pattern Lm on the mask pattern.

Specifically, the evaluation-value calculating unit 16 sets edge points e6A to e8A on the left-side edge line L1 of the line pattern Lm on the mask pattern and sets edge points e6B to e8B on the right-side edge line Lr. Consequently, the edge point pair e6A and 6B, the edge point pair e7A and 7B, and the edge point pair e8A and 8B are set on the mask pattern.

The evaluation-value calculating unit 16 performs the lithography simulation on both side edges (edge points e6A to e8A and e6B to e8B) of the line pattern Lm that are the simulation points (Step S320). Specifically, a second post-lithography pattern 53 that is the post-lithography pattern of the line pattern Lm is derived by performing the lithography simulation on the mask pattern. In the second post-lithography pattern 53, the edge line corresponding to the edge line L1 is s3L and the edge line corresponding to the edge line Lr is s3R.

The evaluation-value calculating unit 16 calculates each of an inter-edge-point distance w6 between a post-lithography edge point e16A and a post-lithography edge point e16B, an inter-edge-point distance w7 between a post-lithography edge point e17A and a post-lithography edge point e17B, and an inter-edge-point distance w8 between a post-lithography edge point e18A and a post-lithography edge point e18B. Then, the evaluation-value calculating unit 16 calculates the average of the distances w6 to w8 as the second evaluation value. In other words, the evaluation-value calculating unit 16 calculates the average of the line widths w6 to w8 by the lithography simulation as the second evaluation value (Step S330).

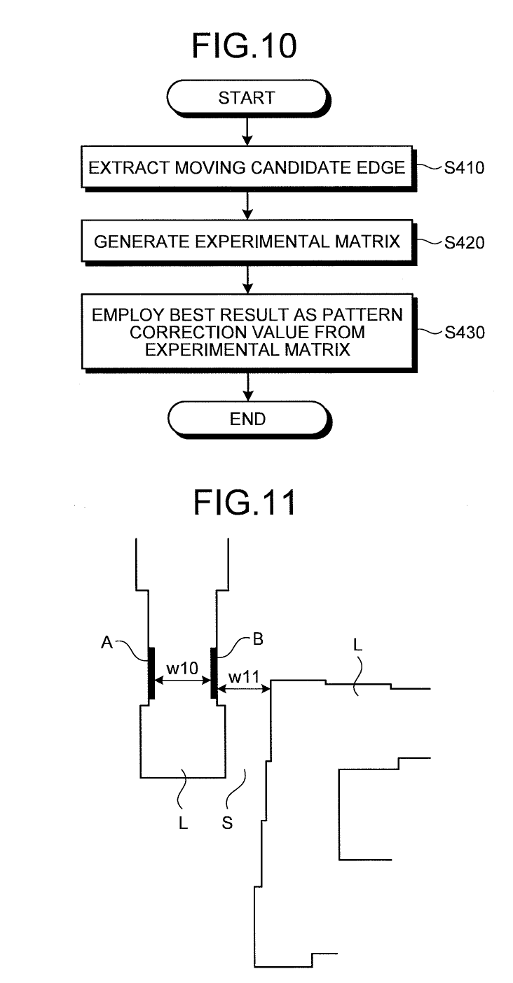

Next, a moving amount setting process of the mask pattern for eliminating the hot spot H is explained. In this example, explanation is given for the process in the case of setting the moving amount of the mask pattern to eliminate the hot spot H based on the second allowable range. FIG. 10 is a flowchart illustrating the setting process procedure of the moving amount of the mask pattern. First, as explained at Step S50 in FIG. 3, the HS extracting unit 17 extracts the moving target edge to be moved on the mask pattern. Specifically, the HS extracting unit 17 extracts a moving candidate edge to be a candidate of the moving target edge from among edges near the hot spot H (Step S410).

The moving-amount determining unit 18 calculates an allowable range (hereinafter, mask allowable range) related to the dimension of the mask pattern based on a constraint condition (hereinafter, mask dimensional constraint condition) related to the dimension of the mask pattern and the actual dimension (hereinafter, mask actual dimension) of the mask pattern. The mask dimensional constraint condition is a lower limit of the line pattern width, a lower limit of a space pattern dimension (inter-line-pattern distance), or the like. In other words, the mask dimensional constraint condition is a minimum width or a minimum space value that the mask pattern shape should satisfy. The mask dimensional constraint condition is set to the moving-amount determining unit 18 of the pattern generating apparatus 1 in advance based on an exposure specification or the like.

FIG. 11 is a diagram for explaining the mask dimensional constraint condition. FIG. 11 illustrates the edges A and B set on the mask pattern. The distance between the edge A and the edge B is a line pattern width w10 (width of the line pattern L) for which the lower limit is set as the constraint condition. Moreover, the distance between the edge B and a different line pattern L adjacent to this edge B is a space dimension w11 (width of the space S) for which the lower limit is set as the constraint condition.

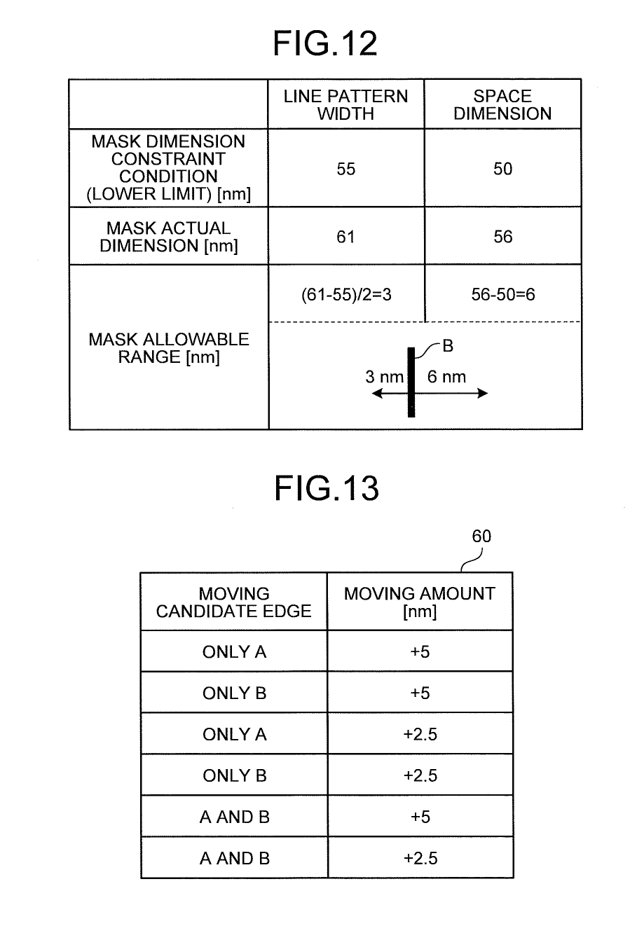

The moving-amount determining unit 18 calculates an allowable range (range in which an edge can be moved) related to the dimension of the mask pattern based on the mask dimensional constraint condition and the mask actual dimension. FIG. 12 is a diagram for explaining the mask allowable range with respect to the mask dimensional constraint condition shown in FIG. 11. FIG. 12 illustrates the case where the lower limit of the line pattern width w10 is defined to 55 nm and the lower limit of the space dimension w11 is defined to 50 nm as the mask dimensional constraint condition. Moreover, FIG. 12 illustrates the case where the line pattern width w10 is 61 nm and the space dimension w11 is 56 nm in the mask actual dimension.

In the case of thickening the line pattern width w10, for example, the edge A and the edge B are moved in a direction in which the line pattern is thickened by the same amount. Moreover, in the case of thickening the space dimension w11, the edge B is moved in a direction in which the space dimension w11 is thickened. In the case of FIG. 11, for thickening the line pattern width w10, the edge A is moved on the left side and the edge B is moved on the right side. Moreover, for thickening the space dimension w11, the edge B is moved on the left side.

Because the lower limit of the line pattern width w10 is 55 nm and the mask actual dimension of the line pattern width w10 is 61 nm, the line pattern width w10 is allowed to be thinned by 61 nm−55 nm=6 nm from the present mask actual dimension. Then, if the edges A and B are moved by the same amount, each of the edges A and B is allowed to move by 6 nm/2=3 nm in a direction in which the line pattern width w10 is narrowed.

Moreover, because the lower limit of the space dimension w11 is 50 nm and the mask actual dimension of the space dimension w11 is 56 nm, the space dimension w11 is allowed to be narrowed by 56 nm−50 nm=6 nm from the present mask actual dimension. Then, because only the edge B is moved, the edge B is allowed to move by 6 nm in a direction in which the space dimension w11 is narrowed. Therefore, the mask allowable range of the edge B is 3 nm on the left side to 6 nm on the right side.

In the following explanation, a moving direction of the edges A and B in which the line pattern width w10 and the space dimension w11 are thickened is defined as a plus-side direction of the edges A and B. Moreover, a moving direction of the edges A and B in which the line pattern width w10 and the space dimension w11 are thinned is defined as a minus-side direction of the edges A and B. Therefore, the case where the edge B moves on the right side when viewed from the line pattern is a movement in the plus direction with respect to the line pattern, and the case where the edge B moves on the right side when viewed from the space pattern is a movement in the minus direction with respect to the space pattern.

The moving-amount determining unit 18 generates an experimental matrix (design of experiments) 60 based on the calculated mask allowable range and a minimum unit (hereinafter, moving-amount minimum unit) of the moving amount by which the edges A and B are moved (Step S420). The experimental matrix 60 is an information table in which the moving candidate edge and the moving amount are correlated with each other. The experimental accuracy becomes high as the moving-amount minimum unit becomes small, and the number of experiments decreases as the moving-amount minimum unit becomes large.

FIG. 13 is a diagram illustrating an example of the experimental matrix with respect to the mask allowable range shown in FIG. 12. FIG. 13 illustrates the case where the moving-amount minimum unit is 2.5 nm. As the moving-amount minimum unit, for example, 2 nm to 3 nm is used. In this example, because the hot spot H is the necking (defect that the lithography simulation shape becomes thin), it is sufficient that the edge B on the line pattern is moved on the plus side. Therefore, in the experimental matrix in this case, as shown in FIG. 13, only a plus moving amount is set to each moving candidate edge.

Specifically, in the case of moving only the edge A, the moving amount of +5 nm and the moving amount of +2.5 nm are allowed. Moreover, in the case of moving only the edge B, the moving amount of +5 nm and the moving amount of +2.5 nm are allowed. Furthermore, in the case of moving both of the edges A and B, the moving amount of +5 nm each and the moving amount of +2.5 nm each are allowed.

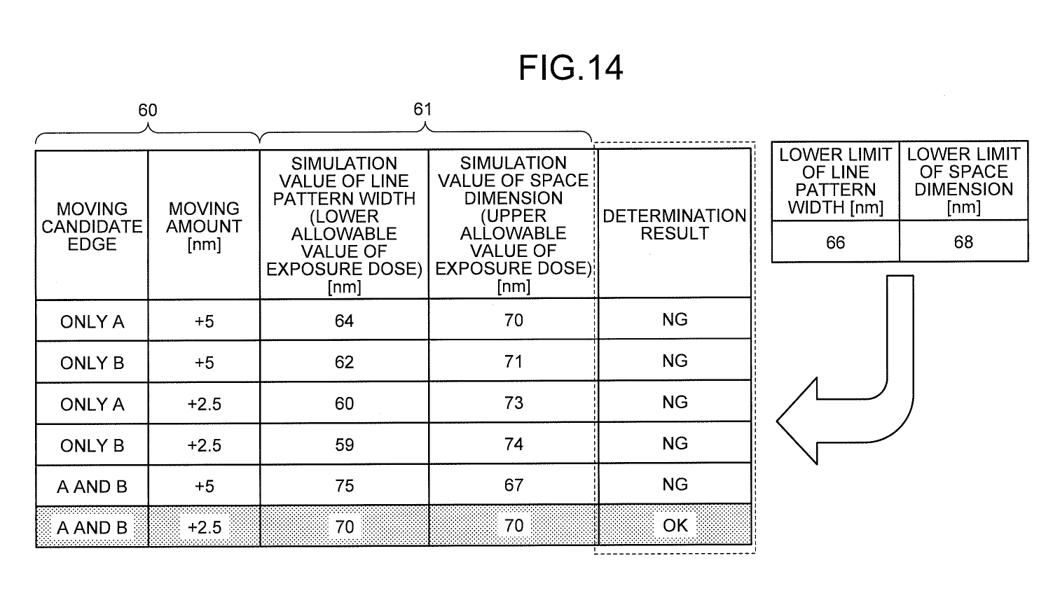

The moving-amount determining unit 18 determines the moving target edge and the moving amount based on the experimental matrix 60 and the lithography simulation result. FIG. 14 is a diagram illustrating a correspondence relationship between the experimental matrix and the lithography simulation result. FIG. 14 illustrates the correspondence relationship between the experimental matrix 60 and a lithography simulation result 61 (second evaluation value) and a determination result indicating whether an edge can be moved. In this example, explanation is given for the case where the second evaluation value is the lithography simulation value illustrated in FIG. 5 or FIG. 9.

As the lithography simulation result 61, the simulation value of the line pattern width w10 in the case of performing the exposure process by using a lower allowable value of an exposure dose, the simulation value of the space dimension w11 in the case of performing the exposure process by using an upper allowable value of an exposure dose are calculated as the second evaluation values. The lower allowable value of an exposure dose is an exposure dose with which the line pattern width w10 becomes thickest, and the upper allowable value of an exposure dose is an exposure dose with which the space dimension w11 becomes widest.

The moving-amount determining unit 18 extracts the combination of the moving candidate edge and the moving amount with which the line pattern width w10 and the space dimension w11 fall within the allowable range from the experimental matrix 60, based on the allowable range (second allowable range) of the lithography simulation value set in advance. For example, when the second allowable range in which the lower limit of the line pattern width w10 is 66 nm and the lower limit of the space dimension w11 is 68 nm is set, the second allowable range is satisfied (determination result is OK) only when both of the edge A and the edge B on the line pattern are moved by 2.5 nm on the plus side (thickening direction). Therefore, the moving-amount determining unit 18 sets the moving candidate edge with which the determination result becomes OK as the moving target edge and moves the moving target edge only by the moving amount with which the determination result becomes OK.

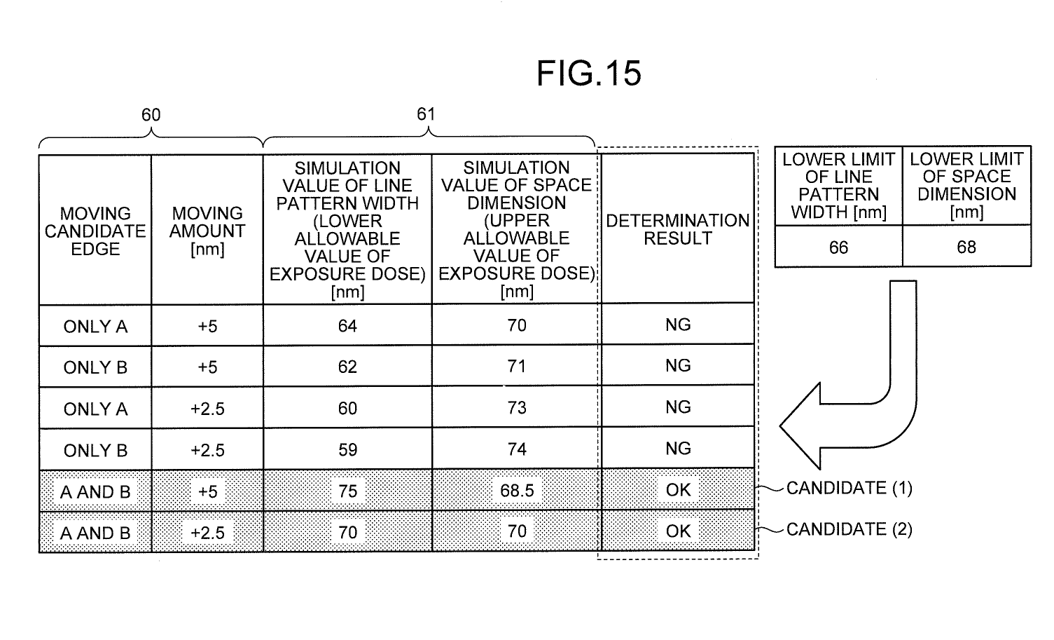

If there is a plurality of items (moving candidate edge) that are determined that the determination result is OK as shown in FIG. 15, the moving-amount determining unit 18, for example, calculates a margin with respect to the second allowable range and determines the moving target edge based on the calculated margin.

FIG. 15 illustrates the case where the case of moving both of the edge A and the edge B by 5 nm on the plus side (candidate 1) and the case of moving both of the edge A and the edge B by 2.5 nm on the plus side (candidate 2) satisfy the second allowable range. In the case of the candidate 1, a space-dimension lithography simulation value is 68.5 nm while the lower limit of the space dimension w11 is 68 nm, so that the margin of the Bridge is low. Therefore, the moving-amount determining unit 18 selects the candidate 2 as the moving target edge by elimination. In other words, the moving-amount determining unit 18 employs the best result for the moving target and the moving amount for the pattern correction from the experimental matrix 60 (Step S430).

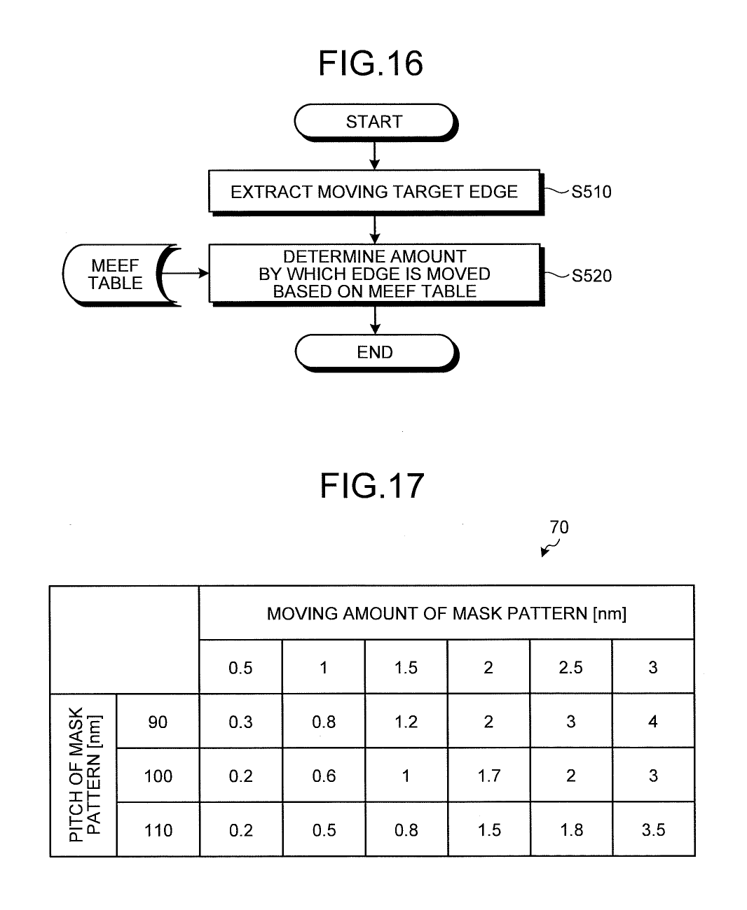

The moving amount of the mask pattern can be determined by using an MEEF (MASK Error Enhancement Factor) table. FIG. 16 is a flowchart illustrating a setting process procedure in the case where the moving amount of the mask pattern is set by using the MEEF table. First, the MEEF table is prepared. The MEEF table is generated by performing the lithography simulation every time the mask pattern is moved a little and correlating the dimension variation of the lithography simulation value with respect to the moving amount of the mask pattern for each pitch (line width+space width) of the mask pattern.

FIG. 17 is a diagram illustrating an example of the MEEF table. An MEEF table 70 is, for example, the dimension variation of the lithography simulation value in the case where the moving amount of the mask pattern is 0.5 nm, 1 nm, 1.5 nm, 2 nm, 2.5 nm, and 3 nm. In the MEEF table 70, the correspondence relationship (correlation) between the moving amount of the mask pattern and the dimension variation of the lithography simulation value is registered, for example, for each of the cases where the pitch of the mask pattern is 90 nm, 100 nm, and 110 nm.

After generating the MEEF table 70, as explained at Step S50 in FIG. 3, the HS extracting unit 17 extracts the moving target edge to be moved on the mask pattern (Step S510). The moving-amount determining unit 18 determines the moving amount of the mask pattern by using the moving target edge, the MEEF table 70, the lithography simulation value, and the second allowable range (Step S520). The moving target edge in this example is the moving target edge extracted by the HS extracting unit 17. Moreover, the lithography simulation value is the lithography simulation value between an edge adjacent to the moving target edge and the moving target edge, and the lithography simulation value at the hot spot H at which the moving target edge is extracted. For example, when the moving target edge is the edge B in FIG. 1, the moving amount of the mask pattern is determined by using the lithography simulation value between the edges A and B.

Explanation is given for the moving amount of the mask pattern in the case where the pitch is 90 nm. For example, when the pitch is 90 nm, the lithography simulation value is 57 nm, and the second allowable range is 60 nm or more, the lithography simulation value is insufficient by 60 nm−57 nm=3 nm to satisfy the second allowable range. Therefore, the moving-amount determining unit 18 checks the moving amount of the mask pattern for gaining the shortage of 3 nm in the MEEF table 70.

It is found by referring to the MEEF table 70 that the lithography simulation value is moved and thickened by a desired value of 3 nm by moving and thickening the mask pattern by 2.5 nm or more. Therefore, the moving-amount determining unit 18 can determine that the Neck error can be avoided by thickening the mask pattern by 2.5 nm. For example, when the moving target edge is the edge B in FIG. 1, the Neck error can be avoided by thickening the mask pattern by 2.5 nm through movement of the edge B on the right side.

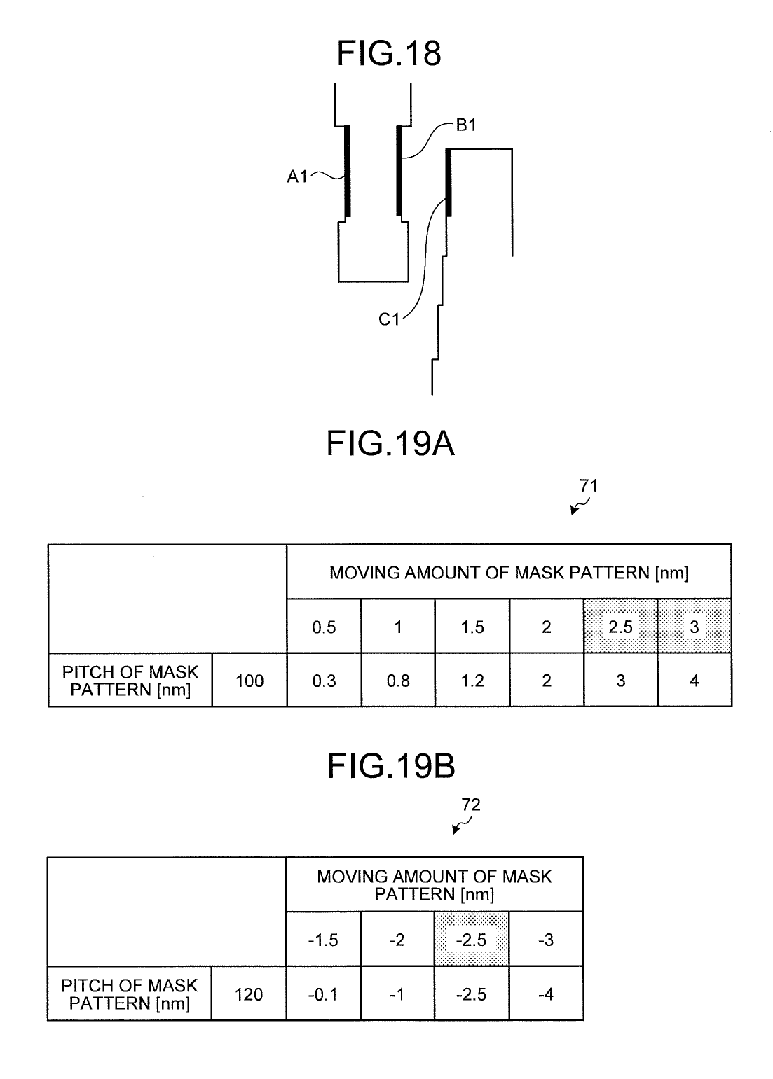

The Neck error and the Bridge error cause an antinomy in some cases. FIG. 18 is a diagram for explaining a mask pattern example in the case where both of the Neck error and the Bridge error are present.

For example, in the mask pattern shown in FIG. 18, the pitch between the edges A1 and B1 is 100 nm and the pitch between edges B1 and C1 is 120 nm. If the lithography simulation value between the edges A1 and B1 is 47 nm when the second allowable range between the edges A1 and B1 is 50 nm or more, the lithography simulation value is insufficient by 50 nm−47 nm=3 nm between the edges A1 and B1.

FIG. 19A and FIG. 19B are diagrams illustrating examples of the MEEF table in the case where the pitch is 100 nm and 120 nm. Referring to an MEEF table 71 shown in FIG. 19A, it is found that when the pitch between the edges is 100 nm, the lithography simulation value moves and is thickened by a desired value of 3 nm by moving and thickening the mask pattern (line pattern) by 2.5 nm or more. Therefore, when the edge B1 is the moving target edge, the Neck error can be avoided by moving the edge B1 by 2.5 nm or more on the edge C1 side on the mask pattern.

Moreover, referring to an MEEF table 72 shown in FIG. 19B, it is found that if the mask pattern (space pattern) is moved by −2.5 nm to narrow the space between the edges B1 and C2, the lithography simulation value moves by −2.5 nm and the space between the edges B1 and C2 is narrowed. Furthermore, it is found that if the mask pattern is moved by −3 nm to narrow the space between the edges B1 and C2, the lithography simulation value moves by −4 nm and the space between the edges B1 and C2 is narrowed.

When the second allowable range between the edges B1 and C1 is 45 nm or more, if the lithography simulation value between the edges B1 and C1 is 48 nm, the space between the edges B1 and C1 has a margin of 48 nm−45 nm=3 nm in the lithography simulation value. Therefore, if the edge B1 is moved by −3 nm as the space pattern, the lithography simulation value moves by −4 nm. Then, the space between the edges B1 and C2 becomes 48 nm−4 nm=44 nm, so that the second evaluation value does not satisfy 45 nm that is the second allowable range.

Thus, the moving-amount determining unit 18 can avoid both of the Neck error and the Bridge error between the edges A1 and B1 by moving the edge B1 as the line pattern by 2.5 nm on the edge C1 side.

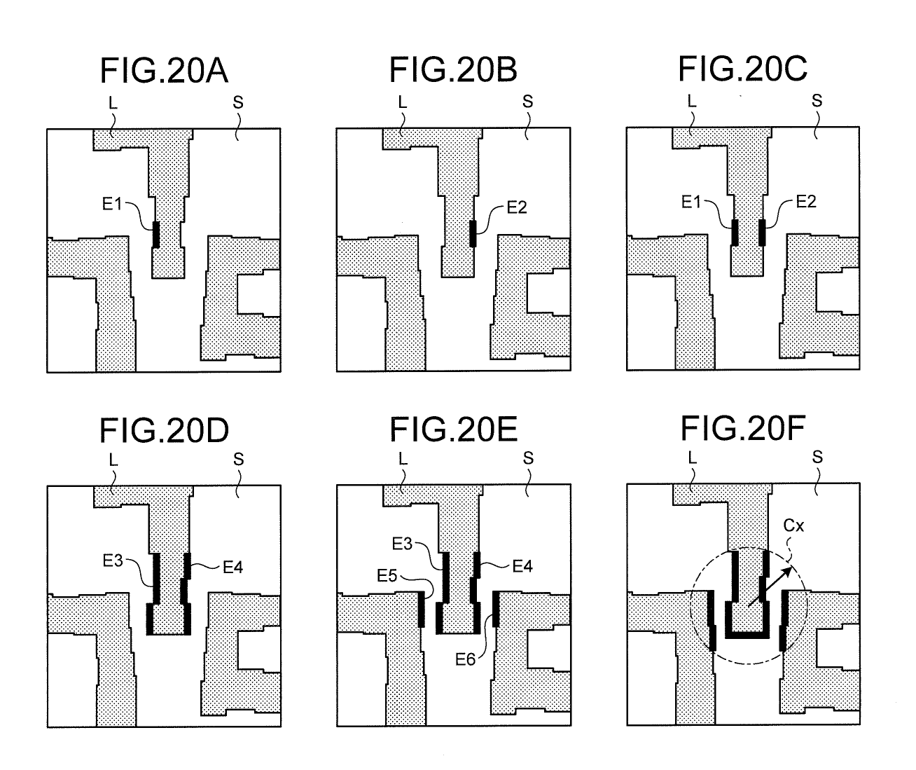

Next, the extracting process of the moving target edge based on the position of the hot spot H is explained. As the extracting process of an edge by the HS extracting unit 17, a plurality of methods is present as shown in FIG. 20A to FIG. 20F. FIG. 20A to FIG. 20F are diagrams for explaining the moving target edge to be the extraction target. FIG. 20A to FIG. 20F illustrate examples of an edge to be extracted as the moving target edge when the hot spot H shown in FIG. 1 is generated.

FIG. 20A to FIG. 20C are examples in the case where the edge closest to the hot spot H is extracted. For example, the HS extracting unit 17 can extract an edge E1 (edge A in FIG. 1) as the edge closest to the hot spot H as shown in FIG. 20A or can extract an edge E2 (edge B in FIG. 1) as the edge closest to the hot spot H as shown in FIG. 20B. Alternatively, the HS extracting unit 17 can extract both of the edges E1 and E2 as the edges closest to the hot spot H as shown in FIG. 20C.

Moreover, FIG. 20D and FIG. 20E are examples in the case where an extraction range of an edge is further expanded. For example, the HS extracting unit 17 can extract edges E3 and E4 in a range wider than the edges E1 and E2 as shown in FIG. 20D. Alternatively, the HS extracting unit 17 can extract any one of the edges E3 and E4. Still alternatively, the HS extracting unit 17 can extract edges E5 and E6 in a range wider than the edges E3 and E4 together with the edges E3 and E4 as shown in FIG. 20E. The edges E5 and E6 in this example are edge patterns on the line pattern different from the edges E3 and E4.

Furthermore, FIG. 20F is an example in the case where all of edges (for example, edges included in an optical radius) in a predetermined range are extracted. As shown in FIG. 20F, the HS extracting unit 17 can extract all of edges in a predetermined distance Cx from the hot spot H.

Although larger number of edges to be extracted leads to expectation of OPC with higher accuracy, the processing time becomes long. Therefore, first, the pattern generating apparatus 1 evaluates whether the hot spot H can be eliminated by moving only one edge as shown in FIG. 20A or FIG. 20B. Then, when the hot spot H is not eliminated by moving one edge, the pattern generating apparatus 1 increases the number or the extraction range of the moving target edge. In this manner, the moving target edge is increased until the hot spot H is eliminated.

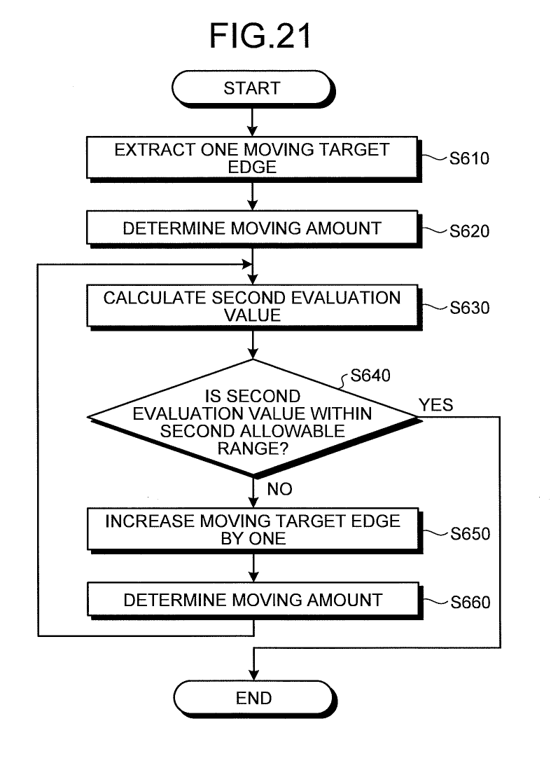

FIG. 21 is a flowchart illustrating a generating process procedure of the mask pattern in the case where the hot spot is eliminated while increasing the moving target edge. Among processes explained in FIG. 21, explanation is omitted for the process similar to the process illustrated in FIG. 3.

After the hot spot H is extracted, the HS extracting unit 17 extracts one edge as the moving target edge for eliminating the hot spot H (Step S610). For example, as shown in FIG. 20A, one edge E1 is extracted. Then, the moving-amount determining unit 18 determines the moving amount of the extracted moving target edge based on the second allowable range (Step S620). Thereafter, the post-lithography-pattern deriving unit 15 calculates the second post-lithography pattern by applying the lithography simulation to the second post-correction pattern that is the mask pattern. Then, the evaluation-value calculating unit 16 calculates the second evaluation value based on the second post-lithography pattern derived by the post-lithography-pattern deriving unit 15 (Step S630).

Thereafter, the HS extracting unit 17 determines whether the hot spot H is eliminated based on whether the second evaluation value calculated by the evaluation-value calculating unit 16 is within the second allowable range (Step S640). When the hot spot H is not eliminated (No at Step S640), the HS extracting unit 17 increases the number of moving target edges to be extracted by one for eliminating the hot spot H (Step S650). For example, the moving target edge to be extracted is increased from one to two, whereby, for example, as shown in FIG. 20C, two edges E1 and E2 are extracted.

The moving-amount determining unit 18 determines the moving amount of the extracted moving target edge based on the second allowable range (Step S660). The post-lithography-pattern deriving unit 15 calculates the second post-lithography pattern by applying the lithography simulation to the second post-correction pattern that is the mask pattern. Then, the evaluation-value calculating unit 16 calculates the second evaluation value based on the second post-lithography pattern derived by the post-lithography-pattern deriving unit 15 (Step S630).

Thereafter, the pattern generating apparatus 1 repeats the processes at Steps S640 to S660 and Step S630 until the hot spot H is eliminated. When the second evaluation value falls within the second allowable range and the hot spot H is eliminated (Yes at Step S640), the correcting unit 19 determines the moving amount of the moving target edge as the pattern correction value.

Explanation is given for the case where the number of moving target edges is increased when the hot spot H is not eliminated; however, the number of moving candidate edges can be increased when the hot spot H is not eliminated.

The correcting process of the mask pattern is performed, for example, for each layer of the wafer process. Then, a semiconductor device is manufactured by using a product mask in which the mask pattern is corrected as needed. Specifically, the first post-correction pattern is generated by using the pre-correction pattern, and the second post-correction pattern is generated by using the first post-correction pattern. Then, a mask is generated by using the second post-correction pattern, exposure is performed on a wafer on which a resist is applied by using the mask, and thereafter, a resist pattern is formed on the wafer by developing the wafer. Then, a lower layer side of the wafer is etched with the resist pattern as a mask.

Consequently, an actual pattern corresponding to the second post-correction pattern is formed on the wafer. When manufacturing a semiconductor device, the above-described correction of the pre-correction mask pattern (generation of the first post-correction pattern), correction of the first post-correction pattern (generation of the second post-correction pattern), exposure process, development process, etching process, and the like are repeated for each layer.

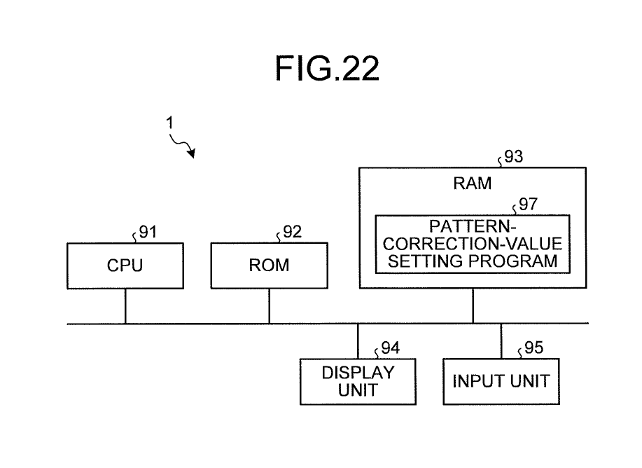

Next, the hardware configuration of the pattern generating apparatus 1 is explained. FIG. 22 is a diagram illustrating the hardware configuration of the pattern generating apparatus. The pattern generating apparatus 1 includes a CPU (Central Processing Unit) 91, a ROM (Read Only Memory) 92, a RAM (Random Access Memory) 93, a display unit 94, and an input unit 95. In the pattern generating apparatus 1, the CPU 91, the ROM 92, the RAM 93, the display unit 94, and the input unit 95 are connected via a bus line.

The CPU 91 executes determination of a pattern by using a pattern-correction-value setting program (mask pattern generation program) 97 that is a computer program. The pattern-correction-value setting program 97 is a program that executes correction (generation) of the mask pattern by the method explained in the present embodiment. The display unit 94 is a display device such as a liquid crystal monitor, and displays the lithography target, the pattern edge, the first evaluation value, the second evaluation value, the pre-correction mask pattern, the first post-correction pattern, the second post-correction pattern, and the like based on an instruction from the CPU 91. The input unit 95 is configured to include a mouse and a keyboard, and inputs instruction information (such as parameter necessary for correction of the mask pattern) that is externally input by a user. The instruction information input to the input unit 95 is sent to the CPU 91.

The pattern-correction-value setting program 97 is stored in the ROM 92 and is loaded to the RAM 93 via the bus line. FIG. 22 illustrates the state where the pattern-correction-value setting program 97 is loaded to the RAM 93.

The CPU 91 executes the pattern-correction-value setting program 97 loaded in the RAM 93. Specifically, in the pattern generating apparatus 1, the CPU 91 reads out the pattern-correction-value setting program 97 from the ROM 92, loads it in a program storage area in the RAM 93, and executes various processes, in accordance with the input of an instruction by a user from the input unit 95. The CPU 91 temporarily stores various data generated in the various processes in the data storage area formed in the RAM 93.

The pattern-correction-value setting program 97 executed in the pattern generating apparatus 1 has a module configuration including the post-lithography-pattern deriving unit 15, the evaluation-value calculating unit 16, the HS extracting unit 17, the moving-amount determining unit 18, and the correcting unit 19, which are loaded in a main storage device, whereby they are generated on the main storage device.

The second evaluation value explained in the present embodiment is one example, and other evaluation indexes can be used as the second evaluation value. Moreover, the first evaluation value explained in the present embodiment is one example, and other evaluation indexes (for example, any of the second evaluation values explained in the present embodiment) can be used as the first evaluation value.

Moreover, in the present embodiment, correction of the mask pattern is performed based on the dimension of the resist pattern; however, correction of the mask pattern can be performed based on the dimension of an actual pattern formed on a wafer after performing a process such as etching from above the resist pattern. In this case, a finished planar shape on the wafer is used as the second evaluation value.

Furthermore, in the present embodiment, the mask pattern is corrected with respect to the line & space pattern; however, the mask pattern can be corrected with respect to a pattern other than the line & space pattern such as a contact hole.

Moreover, in the present embodiment, the resist pattern is derived by the lithography simulation; however, the resist pattern can be derived by using a rule base. Furthermore, the experimental matrix is not limited to the case of being generated by the pattern generating apparatus 1, and can be generated by a different apparatus.

Furthermore, in the present embodiment, when thickening the line pattern width w10, the edge A and the edge B are moved by the same moving amount; however, the edge A and the edge B can be moved by different moving amounts.

In this manner, according to the present embodiment, the mask pattern is corrected based on the second evaluation value different from the first evaluation value after correcting the mask pattern based on the first evaluation value, so that the hot spot can be removed accurately in a short time.

While certain embodiments have been described, these embodiments have been presented by way of example only, and are not intended to limit the scope of the inventions.

Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of generating a mask pattern, comprising:
correcting the mask pattern by moving a first moving target pattern in the mask pattern so that a first evaluation value calculated with respect to a pattern after lithography derived by using the mask pattern satisfies a first condition; and
further correcting a mask pattern after the correcting by moving a second moving target pattern in the mask pattern after the correcting so that a second evaluation value calculated with respect to a pattern after lithography derived by using the mask pattern after the correcting satisfies a second condition.

2. The method according to claim 1, wherein
the first evaluation value is a value related to a pattern dimension after lithography at an evaluation point set on the mask pattern, and
the second evaluation value is a value related to a pattern dimension after lithography calculated at an evaluation point that is newly set by changing an evaluation point that is set when calculating the first evaluation value or adding to the evaluation point.

3. The method according to claim 1, wherein
the further correcting the mask pattern after the correcting includes
calculating a plurality of types of moving amounts by which the second moving target pattern is movable on the mask pattern based on a dimensional constraint value of the mask pattern and an actual dimension of the mask pattern, and
further correcting the mask pattern after the correcting by setting any of the moving amounts as a moving amount of the second moving target pattern based on the second evaluation value in a case where the second moving target pattern is moved by the moving amounts and an allowable condition of the pattern after lithography.

4. The method according to claim 3, wherein the further correcting the mask pattern after the correcting includes, when there is a plurality of types of moving amounts that satisfy the second condition, further correcting the mask pattern after the correcting by setting a moving amount having largest margin with respect to the second condition as a moving amount of the second moving target pattern.

5. The method according to claim 1, wherein the further correcting the mask pattern after the correcting includes further correcting the mask pattern after the correcting based on correspondence information in which a moving amount in a case where the second moving target pattern is moved on the mask pattern and variation of a pattern dimension after lithography in a case where the second moving target pattern is moved on the mask pattern by this moving amount are correlated with each other.

6. The method according to claim 1, further comprising:
deriving a pattern after lithography by using a post-correction mask pattern that is a mask pattern after the further correcting the mask pattern after the correcting; and
further correcting the post-correction mask pattern by increasing number or an extraction range of the second moving target pattern and further moving the second moving target pattern in the post-correction mask pattern when the second evaluation value calculated with respect to this pattern after lithography does not fall within a predetermined allowable range.

7. The method according to claim 5, wherein the correspondence information is information on a mask pattern derived for each pitch.

8. A method of generating a semiconductor device, comprising:
correcting the mask pattern by moving a first moving target pattern in the mask pattern so that a first evaluation value calculated with respect to a pattern after lithography derived by using the mask pattern satisfies a first condition;
further correcting a mask pattern after the correcting by moving a second moving target pattern in the mask pattern after the correcting so that a second evaluation value calculated with respect to a pattern after lithography derived by using the mask pattern after the correcting satisfies a second condition; and
forming a pattern on a substrate by using a mask manufactured by using a mask pattern after the further correcting the mask pattern after the correcting.

9. The method according to claim 8, wherein
the first evaluation value is a value related to a pattern dimension after lithography at an evaluation point set on the mask pattern, and
the second evaluation value is a value related to a pattern dimension after lithography calculated at an evaluation point that is newly set by changing an evaluation point that is set when calculating the first evaluation value or adding to the evaluation point.

10. The method according to claim 8, wherein
the further correcting the mask pattern after the correcting includes
calculating a plurality of types of moving amounts by which the second moving target pattern is movable on the mask pattern based on a dimensional constraint value of the mask pattern and an actual dimension of the mask pattern, and
further correcting the mask pattern after the correcting by setting any of the moving amounts as a moving amount of the second moving target pattern based on the second evaluation value in a case where the second moving target pattern is moved by the moving amounts and an allowable condition of the pattern after lithography.

11. The method according to claim 10, wherein the further correcting the mask pattern after the correcting includes, when there is a plurality of types of moving amounts that satisfy the second condition, further correcting the mask pattern after the correcting by setting a moving amount having largest margin with respect to the second condition as a moving amount of the second moving target pattern.

12. The method according to claim 8, wherein the further correcting the mask pattern after the correcting includes further correcting the mask pattern after the correcting based on correspondence information in which a moving amount in a case where the second moving target pattern is moved on the mask pattern and variation of a pattern dimension after lithography in a case where the second moving target pattern is moved on the mask pattern by this moving amount are correlated with each other.

13. The method according to claim 8, further comprising:
deriving a pattern after lithography by using a post-correction mask pattern that is a mask pattern after the further correcting the mask pattern after the correcting; and
further correcting the post-correction mask pattern by increasing number or an extraction range of the second moving target pattern and further moving the second moving target pattern in the post-correction mask pattern when the second evaluation value calculated with respect to this pattern after lithography does not fall within a predetermined allowable range.

14. The method according to claim 12, wherein the correspondence information is information on a mask pattern derived for each pitch.

15. A computer program product that is executable in a computer and includes a computer readable medium including instructions for generating a mask pattern, the instructions causing the computer to execute:
correcting the mask pattern by moving a first moving target pattern in the mask pattern so that a first evaluation value calculated with respect to a pattern after lithography derived by using the mask pattern satisfies a first condition; and
further correcting a mask pattern after the correcting by moving a second moving target pattern in the mask pattern after the correcting so that a second evaluation value calculated with respect to a pattern after lithography derived by using the mask pattern after the correcting satisfies a second condition.

16. The computer program product according to claim 15, wherein
the first evaluation value is a value related to a pattern dimension after lithography at an evaluation point set on the mask pattern, and
the second evaluation value is a value related to a pattern dimension after lithography calculated at an evaluation point that is newly set by changing an evaluation point that is set when calculating the first evaluation value or adding to the evaluation point.

17. The computer program product according to claim 15, wherein
the further correcting the mask pattern after the correcting includes
calculating a plurality of types of moving amounts by which the second moving target pattern is movable on the mask pattern based on a dimensional constraint value of the mask pattern and an actual dimension of the mask pattern, and
further correcting the mask pattern after the correcting by setting any of the moving amounts as a moving amount of the second moving target pattern based on the second evaluation value in a case where the second moving target pattern is moved by the moving amounts and an allowable condition of the pattern after lithography.

18. The computer program product according to claim 17, wherein the further correcting the mask pattern after the correcting includes, when there is a plurality of types of moving amounts that satisfy the second condition, further correcting the mask pattern after the correcting by setting a moving amount having largest margin with respect to the second condition as a moving amount of the second moving target pattern.

19. The computer program product according to claim 15, wherein the further correcting the mask pattern after the correcting includes further correcting the mask pattern after the correcting based on correspondence information in which a moving amount in a case where the second moving target pattern is moved on the mask pattern and variation of a pattern dimension after lithography in a case where the second moving target pattern is moved on the mask pattern by this moving amount are correlated with each other.

20. The computer program product according to claim 15, further comprising:
deriving a pattern after lithography by using a post-correction mask pattern that is a mask pattern after the further correcting the mask pattern after the correcting; and
further correcting the post-correction mask pattern by increasing number or an extraction range of the second moving target pattern and further moving the second moving target pattern in the post-correction mask pattern when the second evaluation value calculated with respect to this pattern after lithography does not fall within a predetermined allowable range.
